(19) United States
(12) Patent Application Publication
(10) Pub. No.: US 2026/0008667 A1
(43) Pub. Date: Jan. 8, 2026

(54) SEMICONDUCTOR MEMS STRUCTURE AND METHOD OF FORMING THE SAME

(71) Applicant: Taiwan Semiconductor Manufacturing Company, Ltd., Hsinchu (TW)

(72) Inventors: Fei-Lung Lai, New Taipei City (TW); Kuei-Sung Chang, Kaohsiung City (TW)

(21) Appl. No.: 18/960,219

(22) Filed: Nov. 26, 2024

Related U.S. Application Data
(60) Provisional application No. 63/667,186, filed on Jul. 3, 2024.

(51) Int. Cl. B81B 3/00; B81C 1/00

(52) U.S. Cl. CPC B81B 3/001; B81B 3/0005; B81C 1/00968; B81B 2203/0127; B81B 2203/019; B81C 2201/0132; B81C 2201/112; B81C 2201/115

(57) ABSTRACT

A method includes: receiving a first substrate; forming a bonding layer on a second substrate; bonding the second substrate to the first substrate; forming a movable membrane on the second substrate, the forming including performing an etching operation to form a through via through a thickness of the second substrate; and forming a first anti-stiction structure on a surface of the movable membrane. The forming of the first anti-stiction structure is performed at a same time as at least one of the etching operation of the through via and the forming of the bonding layer.

### PRIORITY CLAIM AND CROSS-REFERENCE

This Application claims the benefit of U.S. Provisional Application No. 63/667,186, filed on Jul. 3, 2024, the contents of which are hereby incorporated by reference in their entirety.

### BACKGROUND

Micro-electro mechanical system (MEMS) devices have been recently developed and are commonly utilized in electronic equipment. The MEMS device is a micro-sized device, usually between less than 1 micron and several millimeters in size. The MEMS device is fabricated using semiconductive materials to form mechanical and electrical features. The MEMS device may include a number of elements (e.g., stationary or movable elements) for achieving electro-mechanical functionality. MEMS devices are widely used in various applications, such as motion sensors, pressure sensors, printer nozzles, inertial sensors, accelerometers and gyroscopes. Moreover, MEMS applications are extended to optical applications, such as movable mirrors, and radio frequency (RF) applications, such as RF switches or the like.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIGS. 1A to 1J are cross-sectional views of intermediate structures for a method of manufacturing a semiconductor device, in accordance with some embodiments.

FIGS. 2A to 2F are cross-sectional views of intermediate structures for a deep reactive ion etching (DRIE) operation, in accordance with some embodiments.

FIG. 2G show a cross-sectional view of an enlarged view of vias of the semiconductor device shown in FIG. 1F, in accordance with some embodiments.

FIG. 2H show a plan view and a cross-sectional view, respectively, of an enlarged portion of the semiconductor device shown in FIG. 1F, in accordance with some embodiments.

FIGS. 3A to 3E are cross-sectional views of intermediate structures for a method of manufacturing a semiconductor device, in accordance with some embodiments.

FIGS. 4A to 4G are cross-sectional views of intermediate structures for a method of manufacturing a semiconductor device, in accordance with some embodiments.

FIGS. 5A to 5F are cross-sectional views of intermediate structures for a method of manufacturing a semiconductor device, in accordance with some embodiments.

FIG. 6 is a cross-sectional view of a semiconductor device, in accordance with some embodiments.

FIG. 7 is a flowchart of a method of manufacturing a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

The present disclosure provides a semiconductor micro-electro mechanical system (MEMS) device and its associated manufacturing operations according to various embodiments. Specifically, a MEMS device is illustrated as an exemplary application herein for showing a new technique of realizing contact area reduction between a movable membrane and a substrate facing the movable membrane, so that the issue of membrane stiction can be eliminated or relieved. According to some embodiments, anti-stiction structures with different types and configuration are formed on a movable membrane to aid in contact area reduction. These anti-stiction structures may be in a form of an etched via extending in the movable membrane or a protrusion layer protruding from the movable membrane. The anti-stiction structures can be formed during the formation of other features, and the additional photolithography operations for forming the anti-stiction structures can be omitted. As a result, the manufacturing cost and time for forming the anti-stiction structures can be reduced.

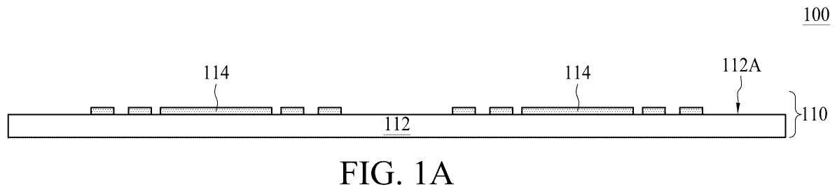

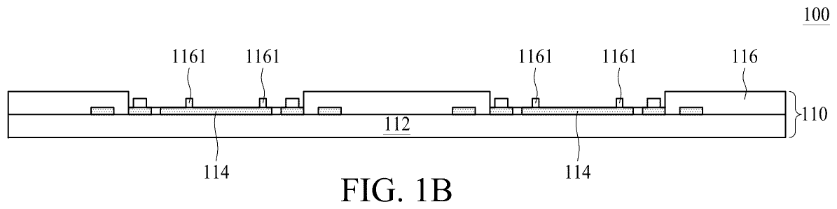

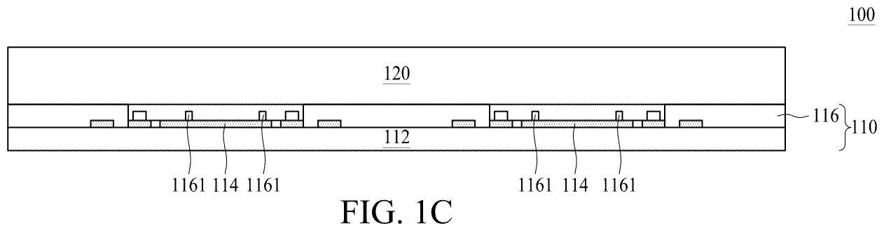

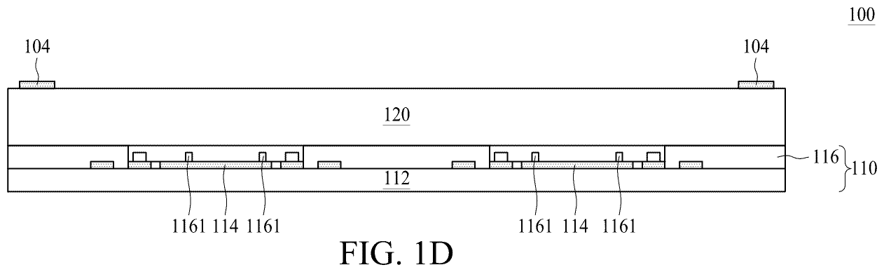

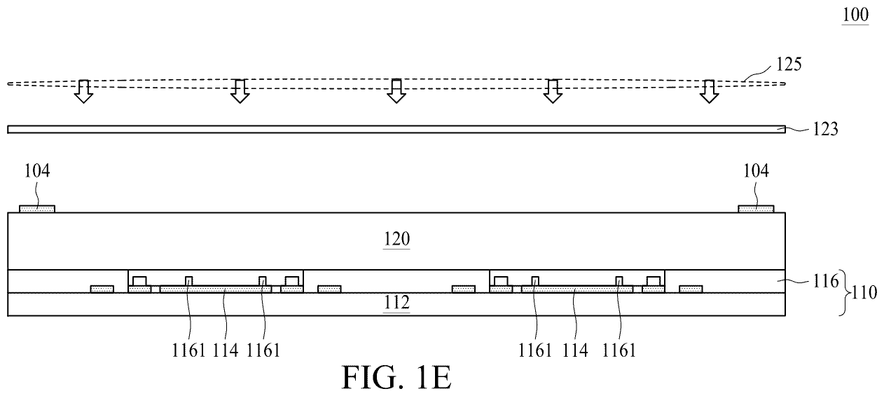

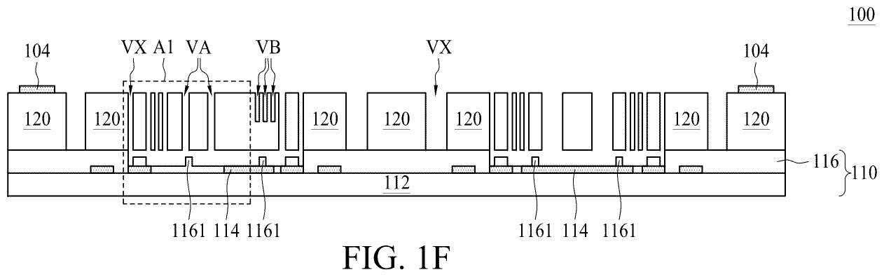

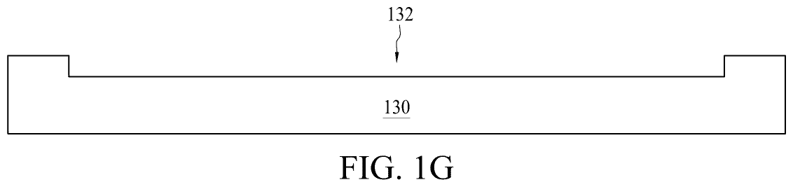

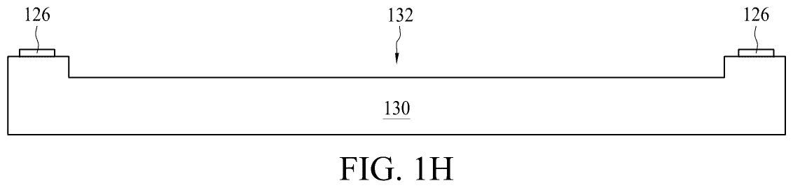

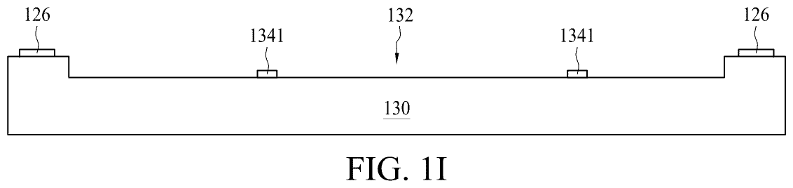

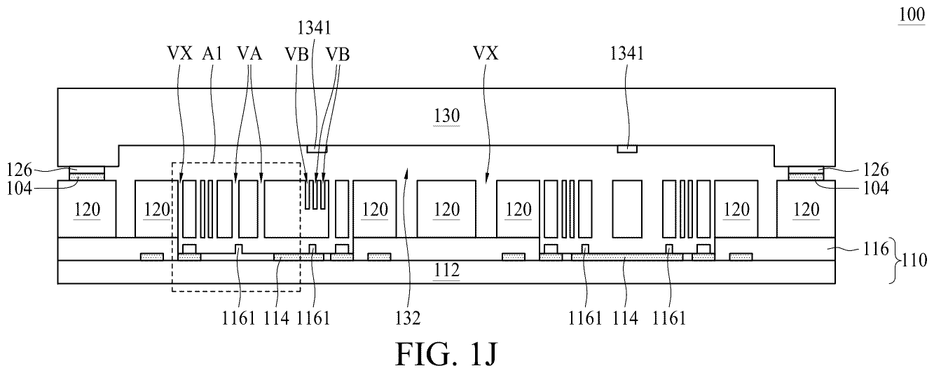

FIGS. 1A to 1J are cross-sectional views of intermediate structures for a method of manufacturing a semiconductor device 100, in accordance with some embodiments. In some embodiments, the semiconductor device 100 is a MEMS device, e.g., a sensor, such as a barometric pressure sensor, a motion sensor, an accelerometer, a gyroscope, or the like. In some embodiments, the semiconductor device 100 includes an optical element for transmitting or receiving optical signals (e.g., an optical waveguide), or an electromagnetic component for processing electromagnetic waves (e.g., an RF circuit).

FIG. 1A shows receiving or providing of a first substrate 110. Initially, a semiconductor material 112 is provided or received. The semiconductor material 112 may be a wafer or a bulk substrate. In some embodiments, the semiconductor material 112 may include silicon, germanium, silicon germanium, silicon carbide, gallium arsenide, or the like. Alternatively, the semiconductor material 112 includes another elementary semiconductor, such as a compound semiconductor including gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or combinations thereof. In yet another embodiment, the semiconductor material 112 is a semiconductor-on-insulator (SOI) substrate. In some embodiments, the semiconductor material 112 may include a doped epitaxial layer, a gradient semiconductor layer, and/or a semiconductor layer overlaying another semiconductor layer of a different type, such as a silicon layer on a silicon germanium layer. The semiconductor material 112 may be doped with an N-type dopant, such as arsenic, phosphor, or the like, or may be doped with a P-type dopant, such as boron or the like.

In some embodiments, the first substrate 110 include electronic circuits (not shown) formed on a front surface 112A of the semiconductor material. The electronic circuits may include doped regions, conductive features, and dielectric materials. In some embodiments, such electronic circuits are configured to form passive circuits, e.g., a capacitor, an inductor, a diode, a fuse, combinations thereof, or the like. In some embodiments, the components are arranged to form active circuitries such as bipolar junction transistors (BJT), field effect transistors (FET), or the like. In some embodiments, the active circuitries include planar-type FETs, fin-type FETs (FinFETs), gate-all-around FETs (e.g., nanowire FETs and nanosheet FETs), or the like.

In some embodiments, the first substrate 110 further includes an interconnect layer (not separately shown) over the foresaid electronic circuits of the semiconductor material 112. The interconnect layer is configured to electrically couple the electronic circuits in the semiconductor material 112 with external devices, such as a second substrate 120 (see FIG. 1C). In some embodiments, the interconnect layer redistributes the interconnection between the first substrate 110 and the second substrate 120, and thus is also termed a “redistribution layer” (RDL). The interconnect layer may include layered conductive lines extending along a horizontal direction where the conductive lines are interconnected through adjacent vertical conductive vias or contacts. The conductive lines and conductive vias/contacts are encapsulated and electrically insulated by an electrically insulating material or an inter-metal dielectric (IMD).

In some embodiments, a conductive layer is deposited over the semiconductor material 112 or the interconnect layer. The conductive layer may include conductive materials, such as doped silicon and metallic materials, e.g., copper, aluminum, silver, gold, titanium, indium, tin, or the like. The conductive layer is deposited over the semiconductor material 112 by physical vapor deposition (PVD), chemical vapor deposition (CVD), atomic layer deposition (ALD), or other suitable deposition operations. A patterning operation may be performed on the conductive layer to form one or more conductive pads 114. The patterning operation may include photolithography and etching operations. The etching operations may include a dry etch, a wet etch, a combination thereof (e.g., a reactive ion etch), or the like. In some embodiments, the conductive pad 114 serve as a sensing electrode or a bond pad for the semiconductor device 100.

Referring to FIG. 1B, an interface layer 116 is deposited over the semiconductor material 112, thereby forming a first substrate 110 along with the semiconductor material 112 and the conductive pads 114. The interface layer 116 may be formed of silicon. In some embodiments, the interface layer 116 is formed of a dielectric material, such as silicon oxide, by a suitable technology, such as thermal oxidation, spin-on coating, CVD, PVD, ALD, and the like. In some embodiments, an etching operation may be performed on the interface layer 116 to expose a portion of the conductive pads 114.

In some embodiments, one or more anti-stiction layers 1161 are formed on the surface of the interface layer 116 or the conductive pads 114. The anti-stiction layer 1161, as its name implies, may be used as an anti-stiction structure to prevent stiction of a movable membrane formed in a second substrate 120 (see FIG. 1F) on the interface layer 116 during movement of the movable membrane. The anti-stiction layer 1161 may reduce the contact area between the movable membrane of the second substrate 120 and the interface layer 116 of the first substrate 110, thereby reducing the likelihood of stiction. In the depicted embodiment, the anti-stiction layers 1161 are formed from the interface layer 116 during a patterning operation of the interface layer 116. Alternatively, the anti-stiction layer 1161 may have a material different from the interface layer 116, and may be formed of a semiconductor material (such as silicon, germanium, or the like), a metallic material (such as copper, aluminum, silver, gold, titanium, indium, tin, or the like), a dielectric material (such as nitride), or the like.

Referring to FIG. 1C, a second substrate 120 is provided or received. The second substrate 120 may be a wafer or a bulk substrate. In some embodiments, the second substrate 120 includes silicon, germanium, silicon germanium, silicon carbide, gallium arsenide, or the like. Alternatively, the second substrate 120 includes another elementary semiconductor, such as a compound semiconductor including gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or combinations thereof. In yet another embodiment, the second substrate 120 is a semiconductor-on-insulator (SOI) substrate. In some embodiments, the second substrate 120 includes a doped epitaxial layer, a gradient semiconductor layer, and/or a semiconductor layer overlaying another semiconductor layer of a different type, such as a silicon layer on a silicon germanium layer. The second substrate 120 may be doped with an N-type dopant, such as arsenic, phosphor, or the like, or may be doped with a P-type dopant, such as boron or the like. The second substrate 120 may include a material similar to the semiconductor material 112. In some embodiments, a surface of the first substrate 110 or the second substrate 120 may be deposited with silicon or a dielectric material (not separately shown) for facilitating fusion bonding with the first substrate 110.

Referring to FIG. 1C, the first substrate 110 is bonded to the second substrate 120. The bonding method may include compressive bonding, fusion bonding, or solid-liquid inter-diffusion bonding (SLID). The fusion bonding enables a direct contact and bonding by silicon or dielectric materials on the first substrate 110 and the second substrate 120. In some embodiments, a thermal annealing is involved in the bonding operation to fuse the second substrate 120 where it makes contact with the first substrate 110.

Referring to FIG. 1D, one or more first bonding layers 104 are formed on an upper surface of the second substrate 120. The first bonding layer 104 may be formed of a conductive material, such as germanium, copper, tungsten, aluminum, silver, gold, combinations thereof, or the like. The first bonding layer 104 is formed by initially depositing a conductive material over the second substrate 120, followed by a lithographic process for patterning the conductive material into desirable shapes, such as a bonding rim or bond pads. In some embodiments, the first bonding layers 104 are formed around a periphery of the second substrate 120.

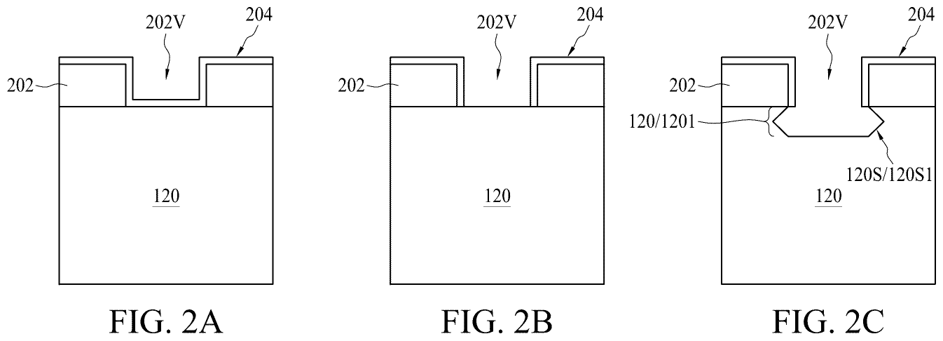

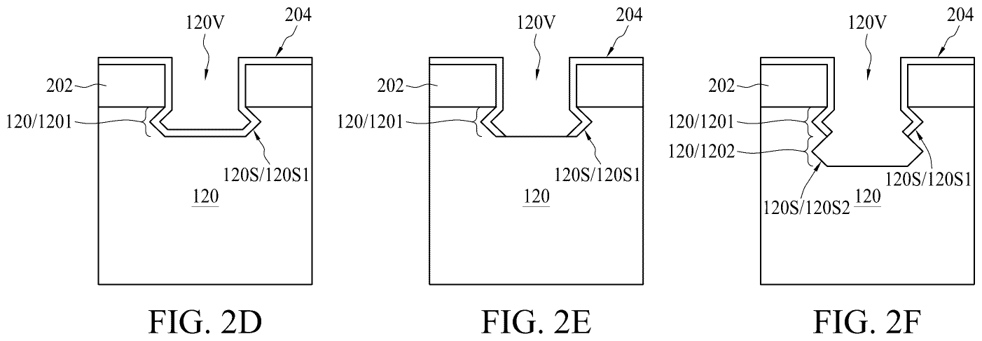

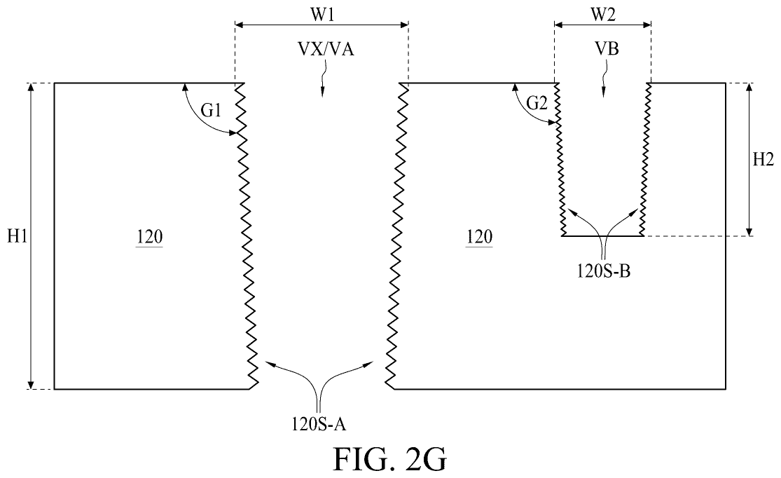

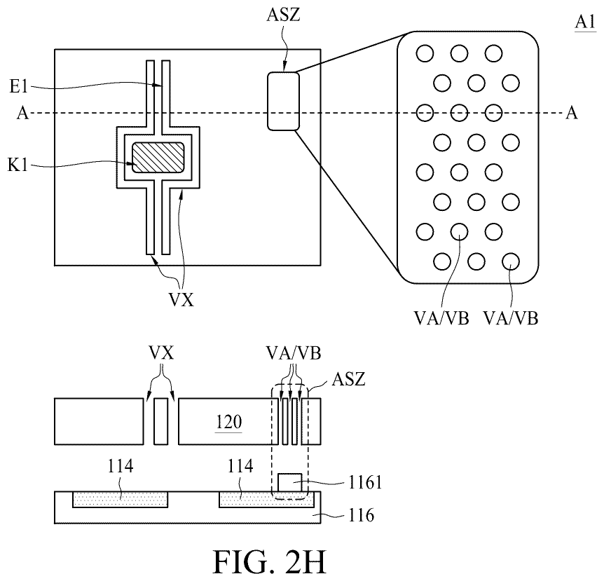

Referring to FIG. 1E, a photolithography operation is performed on the semiconductor device 100. A photomask 123 is arranged over the second substrate 120. A mask layer (not separately shown, but illustrated in FIGS. 2A to 2F as a mask layer 202) is deposited over the second substrate 120. A patterning radiation (or light) beam 125 is introduced to expose on the mask layer. The mask layer may be developed subsequent to the exposure operation to leave a desired pattern of a movable membrane on the mask layer.

Referring to FIG. 1F, after the mask layer is patterned according to the pattern of the photomask 123, an etching operation is performed on the second substrate 120 using the patterned mask layer with an etching mask. When the etching operation is completed, the patterned mask layer may be removed or stripped by an etching operation or an ashing operation. In some embodiments, the etching operation shown in FIG. 1F generates one or more vias VX, which are referred to herein as membrane vias, one or more vias VA, which are referred to herein as etching-through vias, and one or more vias VB, which are referred to herein as non-etching-through vias. The membrane vias VX are one type of etching-through vias used to define a moving element in the membrane of the semiconductor device 100, while vias VA and VB cause the second substrate 120 to restore easily in response to a stimulus, and the movable membrane with such vias VA and VB would become more flexible and robust to a foreign stimulus. Although the membrane vias VX may have a form or shape similar to the etching-through vias VA, they serve different functions in the semiconductor device 100 and arranged in different locations in the semiconductor device 100. For example, the membrane vias VX are formed in any locations in the second substrate 120 without alignment with any anti-stiction layers (e.g., the anti-stiction layer 1161) in the first substrate 110 or an overlying substrate (not separately shown in FIG. 1F, but illustrated as third substrate 130 in FIG. 1J). In other words, the membrane vias VX are used to separate some parts of the second substrate 120 from other parts thereof to define the geometry of the various components, including the movable membrane, in the second substrate 120. The membrane vias VX do not provide anti-stiction functions. In contrast, the etching-through vias VA and the non-etching-through VB are formed to align vertically with one or more anti-stiction layers in the first substrate 110 or the third substrate 130. The vias VA and VB are used as anti-stiction structures to avoid undesired stiction between the movable membrane and other components of the semiconductor device 100. The details of the vias VX, VA and VB are discussed in paragraphs with reference to FIGS. 2A to 2H.

FIGS. 1G to 1J show cross-sectional views of a bonding of a third substrate 130 to the semiconductor device 100, in accordance with some embodiments of the present disclosure. Referring to FIG. 1G, a third substrate 130 is provided or received. The third substrate 130 may be a wafer or a bulk substrate. In some embodiments, the third substrate 130 may include silicon, germanium, silicon germanium, silicon carbide, gallium arsenide, or the like. Alternatively, the third substrate 130 includes another elementary semiconductor, such as a compound semiconductor including gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or combinations thereof. In yet another embodiment, the third substrate 130 is a semiconductor-on-insulator (SOI) substrate. In some embodiments, the third substrate 130 may include a doped epitaxial layer, a gradient semiconductor layer, and/or a semiconductor layer overlaying another semiconductor layer of a different type, such as a silicon layer on a silicon germanium layer. The third substrate 130 may be doped with an N-type dopant, such as arsenic, phosphor, or the like, or may be doped with a P-type dopant, such as boron or the like. The third substrate 130 may include a material similar to the semiconductor material 112 or the second substrate 120. The third substrate 130 may serve as a capping substrate of the semiconductor device 100, and therefore no electronic circuits (except anti-stiction layers or bonding layers) are formed on the third substrate 130.

A patterning operation is performed on the third substrate 130 to form a recess 132 in a central portion of the third substrate 130. The recess 132 may be formed by an etching operation, e.g., a dry etch, a wet etch, a reactive ion etch, or the like.

Referring to FIG. 1H, one or more second bonding layers 126 are formed over the third substrate 130. The second bonding layer 126 is formed by initially depositing a conductive material over the third substrate 130, followed by a lithographic process for patterning the conductive material into desirable shapes, such as a bonding rim or bond pads. The deposition of the second bonding layer 126 can be carried out using any of a variety of techniques, including CVD, LPCVD (low-pressure CVD), PECVD (plasma-enhanced CVD), PVD, sputtering, or the like. In some embodiments, the second bonding layers 126 are formed around a periphery of the third substrate 130.

Referring to FIG. 1I, in some embodiments, one or more anti-stiction layers 1341 are formed on the surface of the third substrate 130. The anti-stiction layer 1341, as its name implies, may be used as an anti-stiction structure to prevent stiction of a movable membrane formed in the second substrate 120 on the third substrate 130 during movement of the membrane. The anti-stiction layer 1341 may reduce the contact area between the movable membrane of the second substrate 120 and the third substrate 130, thereby reducing the likelihood of stiction. In the depicted embodiment, the anti-stiction layers 1341 are formed by depositing a material layer and patterning the material layer. The anti-stiction layer 1341 may be formed of a semiconductor material (such as silicon, germanium, or the like), a metallic material (such as copper, aluminum, silver, gold, titanium, indium, tin, or the like), a dielectric material (such as nitride), or the like. In the depicted example, the anti-stiction layer 1341 are formed of silicon oxide.

Referring to FIG. 1J, the third substrate 130 is bonded to the first substrate 110 through the first bonding layers 104 and the second bonding layers 126. In some embodiments, eutectic bonding is utilized to bond the third substrate 130 and the second substrate 120 through the bonding layers 104 and 126 where the materials selected for the bonding layers 104 and 126 may be AlCu and germanium, respectively, or vice versa.

FIGS. 2A to 2F are cross-sectional views of intermediate structures for a deep reactive ion etching (DRIE) operation shown in FIG. 1F, in accordance with some embodiments. In some embodiments, the DRIE operation is referred to as a Bosch operation. The DRIE operation is a simplified name of a sequence of different operations, and may include cycles of etching and deposition operations. Referring to FIG. 2A, a mask layer 202 is deposited over the second substrate 120 and patterned according to the desired pattern to be formed on the photomask 123. An exemplary via 202V is formed over the second substrate 120 and exposes an upper surface of the second substrate 120.

Initially, a passivation layer 204 is deposited over the mask layer 202. The passivation layer 204 may be formed of a dielectric material, such as silicon oxide. Other types of dielectric materials, such as silicon nitride, silicon carbide, silicon oxynitride, or the like, may also serve as the passivation layer 204. The passivation layer 204 may be deposited using CVD, PVD, ALD, thermal oxidation, or the like. In some embodiments, the passivation layer 204 is conformal to the surface of the patterned mask layer 202.

Referring to FIG. 2B, an etching operation is performed on the via 202V and removes a horizontal portion of the passivation layer 204 at the bottom of the via 202V. Accordingly, the etched passivation layer 204 exposes the upper surface of the second substrate 120. In some embodiments, the etching operation shown in FIG. 2B includes an anisotropic etch that offers a first etching rate in the vertical direction greater than a second etching rate in the horizontal direction. As a result, the bottom portion of the passivation layer 204 is etched with an etch rate greater than that of the sidewall portion of the passivation layer 204.

Referring to FIG. 2C, another etching operation is introduced to etch an upper portion of the second substrate 120. The etching operation forms a via 120V on an upper surface of the second substrate 120. In some embodiments, a sidewall 120S of the via 120V is referred to as a first period in multiple periods of the sidewall 120S of the resulting via 120V (see also the sidewall 120S-A of the via VX/VA or the sidewall 120S-B of the via VB shown in FIG. 2G), and thus can be referred to as a sidewall 120S1. According to some embodiments, the etching operation shown in FIG. 2C is an isotropic etching operation and causes an encroached or concave sidewall 120S1 of the via 120V. The etching operation may include a wet etch. The etching operation may also be a selective etching with the passivation layer 204 serving as an etching mask. Therefore, the etching chemistry can be effective in a downward direction to thereby form the via 120V of a high aspect ratio. After a cycle of the DRIE operation illustrated in FIGS. 2A to 2C, the etched via 120V may include a substantially flat bottom and one period or corrugation structure as the sidewall 120S1 of the etched via 120V.

FIGS. 2D to 2F show another cycle of the DRIE operation that extends the via 120V further downward. Referring to FIG. 2D, a dielectric material of the passivation layer 204 is deposited to extend the existing passivation layer 204 and cover the exposed portions of the second substrate 120 and the via 120V. The extended passivation layer 204 may be formed of a dielectric material, such as silicon oxide. Other types of dielectric materials, such as silicon nitride, silicon carbide, silicon oxynitride, or the like, may also serve as the passivation layer 204. The passivation layer 204 may be deposited using CVD, PVD, ALD, thermal oxidation, or the like. In some embodiments, the passivation layer 204 is conformal to the surface of the patterned mask layer 202 and the via 120V.

Referring to FIG. 2E, an etching operation is performed on the via 202V and removes a horizontal portion of the passivation layer 204 at the bottom of the via 202V near the bottom of the sidewall 102S1. Accordingly, the etched passivation layer 204 exposes another upper surface of the second substrate 120. In some embodiments, the etching operation includes an anisotropic etch that offers a first etching rate in the vertical direction greater than a second etching rate in the horizontal direction. As a result, the portion of the passivation layer 204 at the bottom near the sidewall 120S1 is etched with an etch rate greater than that at the sidewall 120S1.

Referring to FIG. 2F, another etching operation is adopted to etch a portion of the second substrate 120 exposed from the passivation layer 204. The etching operation extends the via 120V to generate another via with sidewalls 120S2. In some embodiments, the sidewall 120S2 of the via 120V is referred to as a second period or corrugation structure in multiple periods or corrugation structures in the sidewall 120S of the resulting via 120V (see also the sidewall 120S-A of the via VX/VA or the sidewall 120S-B of the via VB shown in FIG. 2G), and thus can be referred to as a sidewall 120S2. According to some embodiments, the etching operation shown in FIG. 2F is an isotropic etching operation and causes an encroached or concave sidewall 120S2 of the via 120V. The etching operation may include a wet etch. The etching operation may also be a selective etching with the passivation layer 204 serving as an etching mask. Therefore, the etching chemistry can be effective in a downward direction to thereby form the via 120V of a high aspect ratio. After a cycle of the DRIE operation illustrated in FIGS. 2D to 2F, the etched via 120V may include a substantially flat bottom and two periods or corrugation structures on the sidewalls 120S1 and 120S2 of the etched via 120V.

In some embodiments, the forming of the movable membrane through patterning the second substrate 120 can be accomplished by performing the DRIE operations with multiple cycles shown in FIGS. 2A to 2C or FIGS. 2D to 2F. With help of the passivation layer 204 formed on the sidewalls of the via 120V immediately following a new period or corrugation structure at the bottom of the via 120V, the sidewalls of the as-formed new period of the via 120V can be protected from being further etched, and most of the etching effect can be directed to the downward direction. As a result, the DRIE operation is advantageous in forming a via in a relatively thick substrate, e.g., the second substrate 120 may have a thickness of up to about 30 μm.

FIG. 2G show a cross-sectional view of an enlarged view of vias VX, VA and VB shown in FIG. 1F, in accordance with some embodiments. The vias VX, VA and VB are formed using the DRIE operation described with reference to FIGS. 2A to 2F. In some embodiments, the vias VX and VA are etching-through vias while the via VB is a non-etching-through via. In various embodiments, as used herein, an etching-through via is a via that extends through a full height or thickness of a corresponding structure (e.g., through a thickness H1 of the second substrate 120) and a non-etching-through via is a via that has a height less than the height or thickness of the corresponding structure. The vias VX and VA includes a predetermined width or diameter W1, and the via VB includes a predetermined width or diameter W2. In some embodiments, the width W2 of the non-etching-through via VB is less than the width W1 of the vias VX and VA. Therefore, an aspect ratio H1/W2 of the via VB is greater than an aspect ratio H1/W1 of the vias VX and VA, where the parameter H1 represents the thickness of the second substrate 120 or the height of the membrane via VX or the etching-through via VA. In some embodiments, the width W2 of the via VB is less than about 2 μm.

Since the via VB has a width W2 less than that of the vias VX and VA, e.g., less than about 2 μm, the supply of the reactant chemistry for etching the via VB may be less than that for etching the vias VX and VA during the DRIE operation due to the loading effect. As a result, an etching rate on the via VX or VA is greater than an etching rate on the via VB. With appropriate etching recipe arrangements, the vias VX, VA and the via VB can be etched under a single DRIE operation with the same etching conditions and the shared etching photomask, but the etching rate of forming the via VX or VA can be greater than the etching rate of forming the via VB. Thus, the vias VX, VA and the via VB can be formed under a single etching operation. The vias VA and VB serve similar anti-stiction functions for the second substrate 120, and it is possible that only one type of the vias VA and VB, e.g., only the via VA or the via VB, is present along with the membrane via VX in the semiconductor device 100, and the abovementioned different via arrangements are depending upon different application designs. Since the formation of the vias VA and VB can be achieved during the formation of the membrane via VX, the otherwise additional photomask for forming the via VA or VB can be saved. As a result, the cost and processing time of manufacturing the semiconductor device 100 can be further reduced.

According to some embodiments, since the via VA and the via VB are formed with a shared photomask and a shared DRIE operation with those of the via VX, the number of cycles of the deposition/etching operations as exemplified in FIGS. 2D to 2F would be the same for the vias VX, VA and VB. That means, with the proposed single-photomask etching scheme, the number of periods or corrugation structures on sidewalls 120S-A of the vias VX/VA is equal to the number of periods or corrugation structures on sidewalls 120S-B of the non-etching-through via VB. The differences would lie in that the height or thickness of each period or corrugation structure of the vias VX/VA is greater than that of the via VB due to different etching rates.

According to some embodiments, when the etching rates for etching the via VX and VA are made much greater than the etching rate for the via VB, the via VX or VA may be etched through the second substrate 120 while the via VB still needs more etching cycles to arrive at the predetermined via depth. In that situation, the number of periods or corrugation structures on sidewalls 120S-A of the vias VX/VA is less than the periods or corrugation structures on sidewalls 120S-B of the via VB by, e.g., 0% to 40% of the number of the periods on the sidewalls 120S-B.

In some embodiments, an aspect ratio H1/W2 of the via VB is in a range between about 2 and about 500. In some embodiments, an aspect ratio H1/W1 of the via VA is less than about 2. In some embodiments, the via VA tapers from a top surface of the second substrate 120 to a bottom of the second substrate 120. The via VA forms an obtuse angle G1 between the sidewall 120S-A of the via VA and the upper surface of the second substrate 120. Similarly, in some embodiments, the via VB tapers from a top surface of the second substrate 120 to a bottom of the second substrate 120. The via VB forms an obtuse angle G2 between the sidewall 120S-B of the via VB and the upper surface of the second substrate 120. The included angle G1 is less than the included angle G2 due to a greater etching rate for the via VB than that for the via VB.

When the aspect ratio H1/W2 of the via VB is determined to be in the range between about 2 and about 500, the tapered sidewalls 120S-B of the via VB would close the via VB at some depth of the second substrate 120 before the bottom of the via VB reaches or runs through the bottom of the second substrate 120. On one hand, if the aspect ratio H1/W2 is less than about 2, the etching rate would be too fast so that the sidewalls 120S-B of the via VB would not close before the etch runs through the entire thickness of the second substrate 120. On the other hand, if the aspect ratio H1/W2 is greater than about 500, the etching rate would be relatively too slow so that the etch may not be able to remove the material of the second substrate 120 and form the via VB successfully. Similarly, when the aspect ratio H1/W1 of the via VA is determined to be less than about 1, that means the width W1 is relatively large compared to the thickness H1 of the second substrate 120. Thus, the bottom of the via VA would not close even the bottom of the via VA reaches the bottom of the second substrate 120 during the DRIE operation. According to some embodiments, since the etching rage of the via VA in the vertical direction is greater than the etching rate of the via VB in the vertical direction, the included obtuse angle G2 of the via VB is greater than the obtuse angle G1 of the via VA. In some embodiments, the angle G2 is greater than the angle G1 by at least 0.5 degree. In some embodiments, the length, depth or height H2 of the via VB is in a range between about 5% and about 80%, such as about 40%, of the thickness H1 of the second substrate 120.

FIG. 2H show a plan view and a cross-sectional view, respectively, of an enlarged portion A1 of the semiconductor device 100 shown in FIG. 1F, in accordance with some embodiments. The portion A1 may include a movable element E1, an anchor element K1, and an ASZ arranged in predetermined locations of the movable membrane of the second substrate 120. In some embodiments, the ASZ is an anti-stiction zone of the semiconductor device 100. The movable element E1 may be configured to move torsionally, vertically or horizontally like a spring, and the anchor element K1 may be used to fix one end of the movable element E1 during movement of the movable element E1. The anchor element K1 may be bonded to the first substrate 110 and/or the third substrate 130 to keep immobile during movement of the membrane in the second substrate 120. The anchor element K1 and the movable element E1 may work together to cause a flexible part of the movable membrane around the ASZ to move and perform a specific task, e.g., to perform data sensing in response to external stimuli or is configured to move in response to a control signal. In some embodiments, the via VX is formed to define and form the movable part, such as the movable element E1, in the movable membrane of the second substrate 120.

In some embodiments, the ASZ used for including the vias VA (also including vias VB although not separately illustrated) are defined as an area vertically aligned with the anti-stiction layer 1161 or 1341 from a top-view perspective. The ASZ has an area greater than an area of the anti-stiction layer 1161 from a top-view perspective. In some embodiments, the ASZ has an area at least twice the upper area of the anti-stiction layer 1161 or 1341 from a top-view perspective. In some alternative embodiments, the ASZ has a ring-shaped buffer area in a peripheral region of the ASZ, in which the buffer area has a width of at least 2 μm. In some embodiments, the ASZ includes an array of vias VA or VB away from a periphery of the ASZ. In some embodiments, a via density of the ASZ is defined as an area sum of the vias VA or VB in the ASZ to the area of the ASZ. The via density may be in a range between about 1% and about 95%. If the via density is less than about 1%, the effect of contact area reduction offered by the vias VA or VB may not be noticeable. If the via density is greater than about 95%, there may not be sufficient space between the adjacent vias VA or VB, and the mechanical strength of the movable membrane around the ASZ may not be sufficient to keep the ASZ intact during movement of the movable membrane.

In some embodiments, the vias VA or VB are formed in the ASZ of the movable membrane where stiction is likely to occur, for improving the anti-stiction performance of the movable membrane. In some embodiments, the ASZ is aligned with an anti-stiction layer 1161 or 1341 in the vertical direction. In some embodiments, the ASZ is overlapped with the anti-stiction layer 1161 or 1341 from a top-view perspective. In some embodiments where the contact area provided by the vias VA or VB fulfills the design requirements, the anti-stiction layer 1161 or 1341 can be omitted from the semiconductor device 100. In some embodiments, the vias VA or VB include a circular shape, a polygonal shape, or a strip shape, from a top-view perspective.

As discussed previously, the vias VA or VB can provide the advantage of reducing the contact area with the first substrate 110. According to some embodiments, the vias VA are adopted for achieving contact area reduction in both directions toward the anti-stiction layers 1161 and 1341 in the first substrate 110 and the third substrate 130, respectively. Further, the etching-through vias VA can be specifically arranged on the movable membrane to allow for more flexibility of the movable membrane. According to some embodiments, the vias VB are adopted since they can provide additional mechanical rigidity of the second substrate 120 as compared to the etching-through vias VA. The vias VA and VB and be selected alone or in combination to achieve the desired membrane performance and the anti-stiction effect.

Existing approaches attempt to form the via VA and the via VB using different etching operations along with separate photomasks. However, such approaches may not be effective and efficient in production cost and processing time due to the additional photomask for forming the via VB. In contrast, the proposed etching method can generate the etching-through via VA and the non-etching-through via VB with a shared photomask and a shared etching operation. The processing time and cost can be saved accordingly.

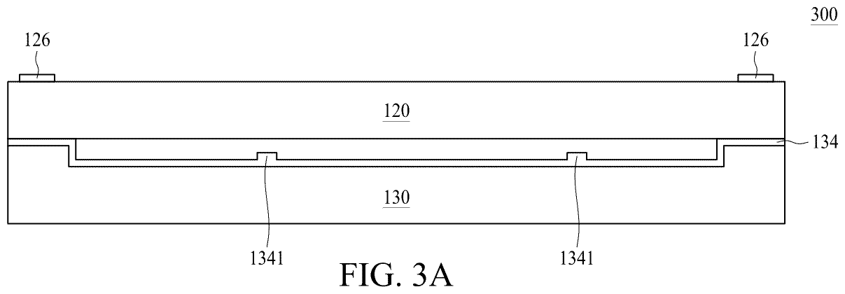

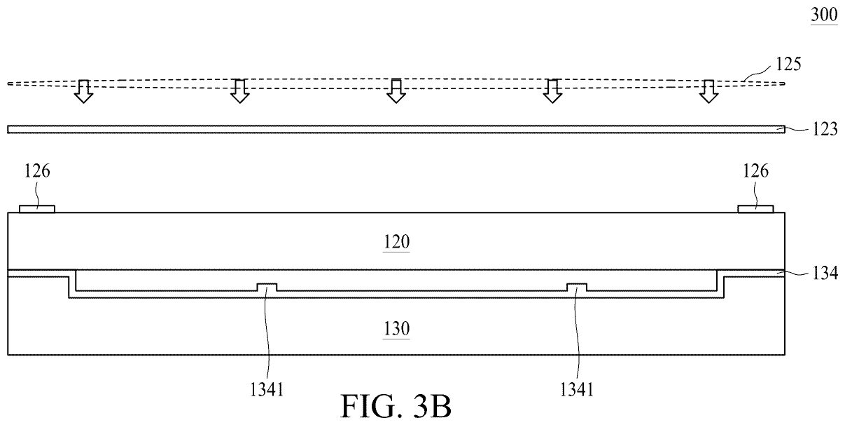

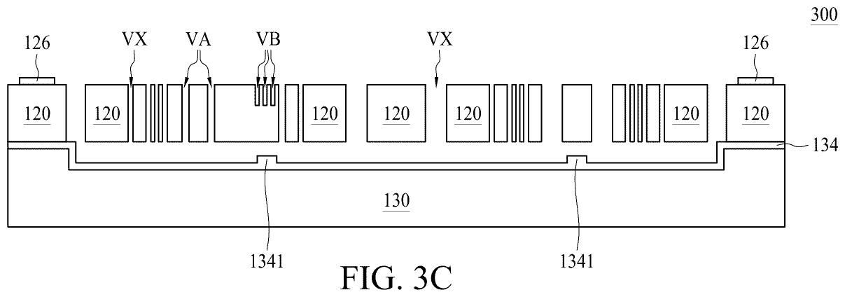

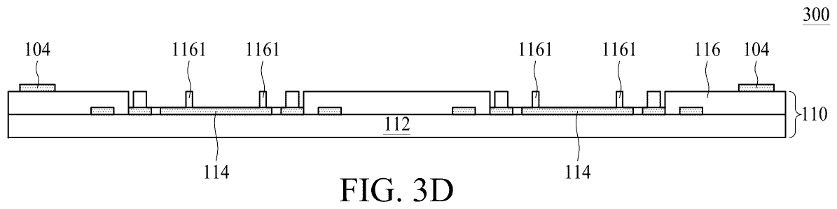

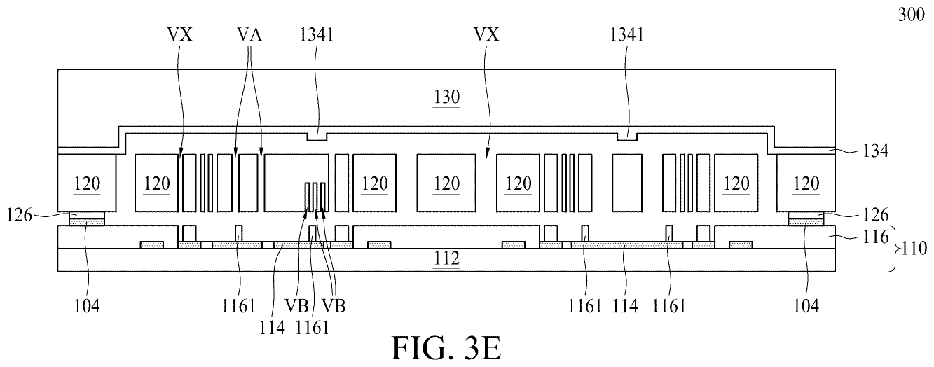

FIGS. 3A to 3E are cross-sectional views of intermediate structures for a method of manufacturing a semiconductor device 300, in accordance with some embodiments. In some embodiments, the semiconductor device 300 is a MEMS device, e.g., a sensor, such as a barometric pressure sensor, a motion sensor, an accelerometer, a gyroscope, or the like. In some embodiments, the semiconductor device 300 includes an optical element for transmitting or receiving optical signals (e.g., an optical waveguide), or an electromagnetic component for processing electromagnetic waves (e.g., an RF circuit). The semiconductor device 300 may be similar to the semiconductor device 100 in many aspects, and these features are labelled with numerals similar to those used in FIGS. 1A to 1J and FIGS. 2A to 2H. Thus, details of these similar features are not repeated for brevity.

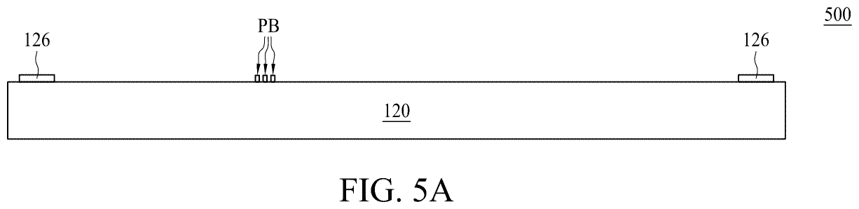

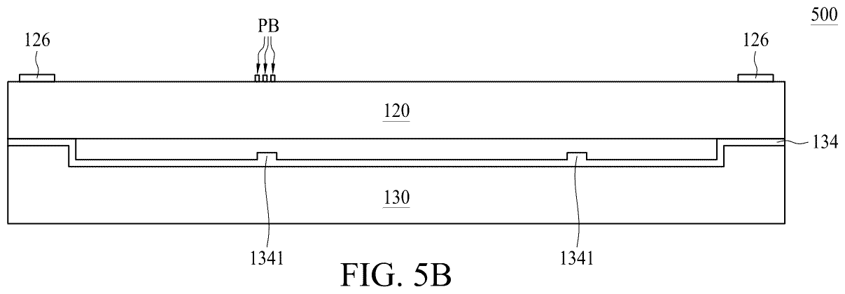

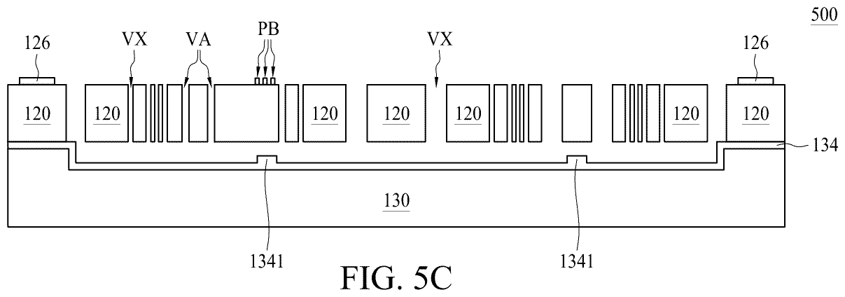

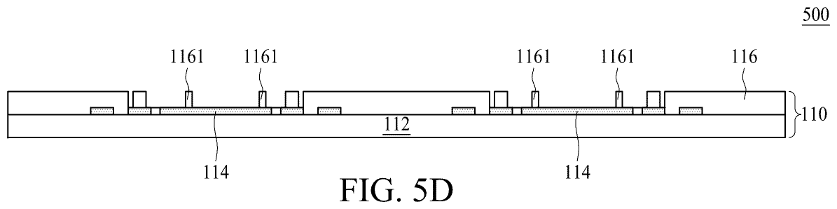

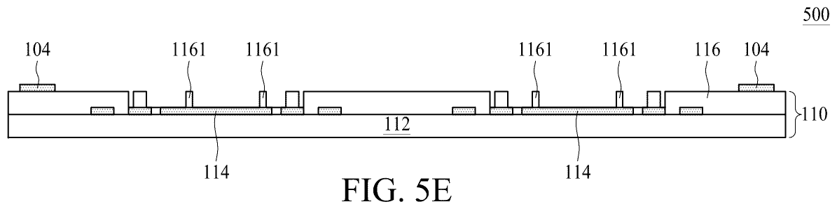

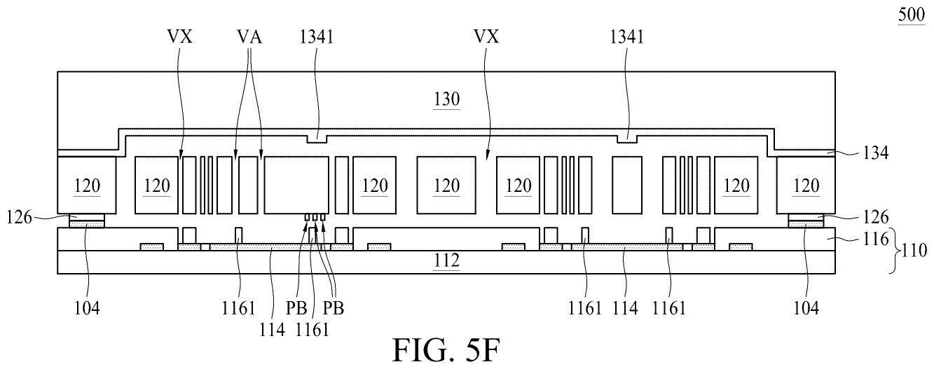

Referring to FIG. 3A, a second substrate 120 and a third substrate 130 are provided or received. The third semiconductor device 300 further includes a third bonding layer 134 and one or more anti-stiction layers 1341 on the third substrate 130. The anti-stiction layers 1341 may be formed by deposition of the third bonding layer 134, followed by patterning the third bonding layer 134 or forming the anti-stiction layers 1341 over the third bonding layer 134. The second substrate 120 is bonded to the third substrate 130 through the third bonding layer 134 in a manner similar to the bonding operation for bonding the first substrate 110 and the second substrate 120 shown with reference to FIG. 1C or FIGS. 5A and 5B. Further, one or more second bonding layers 126 are formed on a surface of the second substrate 120 in a manner similar to that described with reference to FIG. 1H.

FIGS. 3B and 3C show a photolithography operation and an etching operation, respectively, on the second substrate 120 to form vias VX, VA and VB in a manner similar to that described with reference to FIGS. 1E and 1F. One or more vias VX, one or more vias VA and one or more vias VB are formed on an upper surface of the second substrate 120 facing away from the third substrate 130.

Referring to FIG. 3D, a first substrate 110 including one or more conductive pads 114, an interface layer 116 and a plurality of anti-stiction layers 1161 is formed in a manner similar to those described with reference to FIGS. 1A and 1B. Further, one or more first bonding layer 104 are formed on a surface of the interface layer 116. The materials, configurations and methods of forming for the aforesaid elements of the first bonding layer 104 are similar to those described with reference to FIG. 1D.

Referring to FIG. 3E, the second substrate 120 is bonded to the first substrate 110 through the first bonding layers 104 and the second bonding layers 126 in a manner similar to that described with reference to FIG. 1J.

Referring to FIG. 1J and FIG. 3E, the semiconductor device 300 is different from the semiconductor device 100 mainly in that the vias VB of the semiconductor device 300 are arranged as facing the first substrate 110 or the anti-stiction layer 1161, while the vias VB of the semiconductor device 100 are arranged as facing away from the first substrate 110. The semiconductor device 300 supports another design option that can reduce the contact area between the first substrate 110 and the movable membrane of the second substrate 120 for accommodating different application requirements.

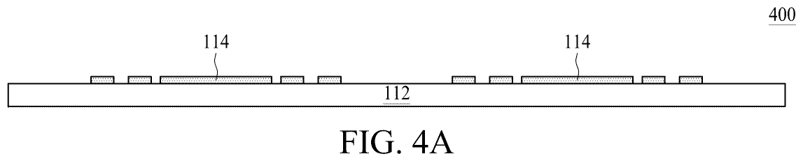

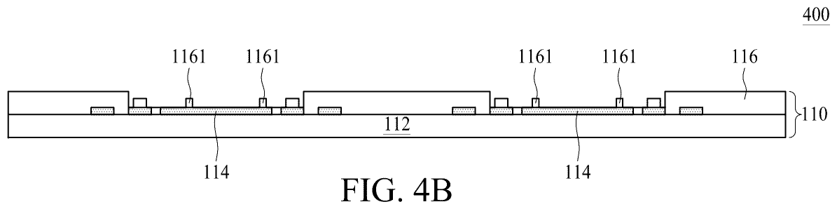

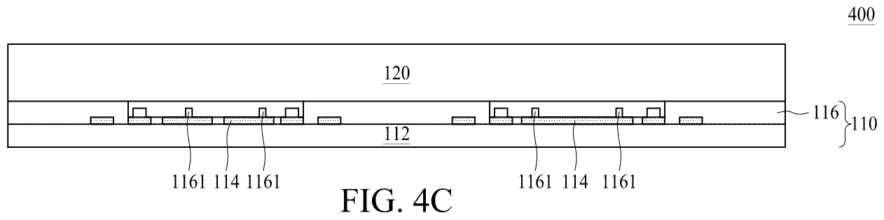

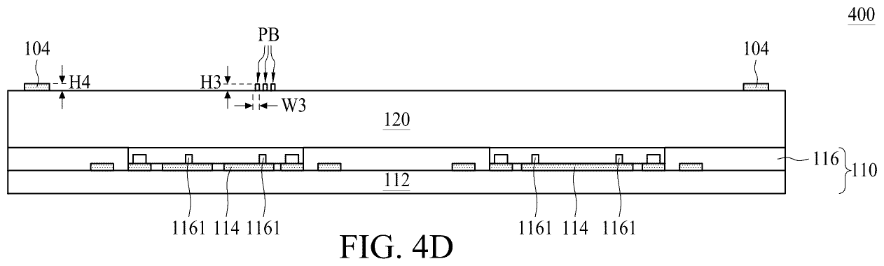

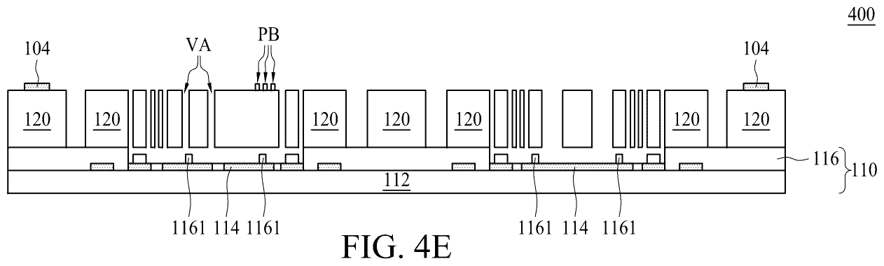

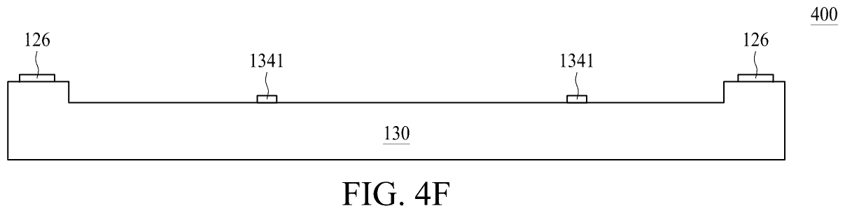

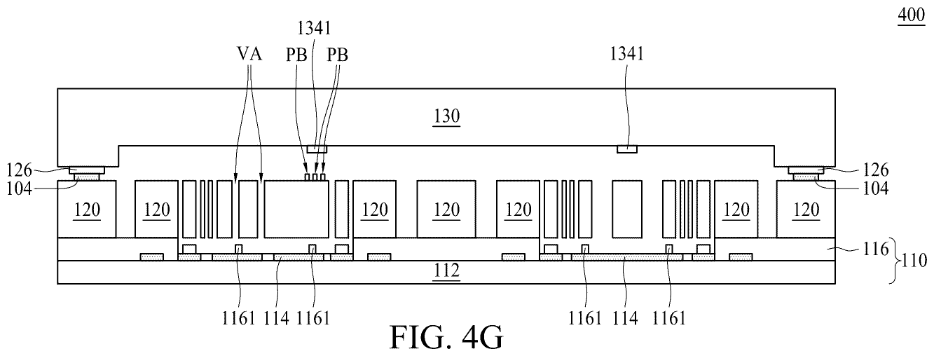

FIGS. 4A to 4G are cross-sectional views of intermediate structures for a method of manufacturing a semiconductor device 400, in accordance with some embodiments. In some embodiments, the semiconductor device 400 is a MEMS device, e.g., a sensor, such as a barometric pressure sensor, a motion sensor, an accelerometer, a gyroscope, or the like. In some embodiments, the semiconductor device 400 includes an optical element for transmitting or receiving optical signals (e.g., an optical waveguide), or an electromagnetic component for processing electromagnetic waves (e.g., an RF circuit). The semiconductor device 400 may be similar to the semiconductor device 100 or 300 in many aspects, and these features are labelled with numerals similar to those used in FIGS. 1A to 1J and FIGS. 2A to 2H. Thus, details of these similar features are not repeated for brevity.

Referring to FIG. 4A to FIG. 4C, a first substrate 110 and a second substrate 120 are provided or received, in which the first substrate 110 is bonded to the second substrate 120 in a manner similar to that described with reference to FIGS. 1A to 1C.

Referring to FIG. 4D, one or more first bonding layers 104 and one or more protrusion layers PB are formed on and protruding from an upper surface of the second substrate 120. The protrusion layers PB may be used as another form of the anti-stiction structure of the present disclosure since the protrusion layers PB can also provide the advantage of reducing the contact area between the movable membrane and the adjacent substrate, e.g., the first substrate 110 or the third substrate 130. In some embodiments, a material layer of the first bonding layer 104 is deposited over the upper surface of the second substrate 120. A patterning operation is performed on the material layer to simultaneously form the first bonding layers 104 as well as the protrusion layers PB during a same lithography operation and a same etching operation. Therefore, the protrusion layer PB may include a material same as the first bonding layer 104. In some embodiments, the material of the first bonding layers 104 or the protrusion layers PB includes a semiconductor material (such as silicon, germanium, or the like), a metallic material (such as copper, aluminum, silver, gold, titanium, indium, tin, or the like), a dielectric material (such as nitride), or the like. In some embodiments, the first bonding layer 104 or the protrusion layer PB includes a circular shape, a polygonal shape, or a strip shape, from a top-view perspective. The protrusion layers PB may be arranged in a line, in a circle, or in an array of holes or posts from a top-view perspective. Each of the protrusion layers PB may have equal or non-equal upper areas, any may have the same or different shapes from a top-view perspective.

In some embodiments, a height H3 of the protrusion layers PB is substantially equal to a height H4 of the first bonding layer 104. In some embodiments, the protrusion layers PB are formed in a form of an array and arranged to be aligned with an ASZ in the first substrate 110 or the third substrate 130. In some embodiments, the array of the protrusion layers PB has a layer density defined as an area sum of the protrusion layers PB in a corresponding ASZ to the area of the ASZ. The layer density may be in a range between about 5% and about 95%. If the protrusion density is greater than about 95%, the effect of contact area reduction offered by the protrusion layers PB may not be noticeable. If the protrusion density is less than about 5%, there may not be sufficient mechanical strength of the PB protrusion around the ASZ to keep the ASZ intact during movement of the movable membrane.

Referring to FIG. 4E, a photolithography and etching operation is performed on the second substrate 120 to form one or more vias VX and VA in a manner similar to that described with reference to FIGS. 1E and 1F. In some embodiments, no non-etching-through vias VB are formed during the photolithography and etching operation shown in FIG. 4F since the protrusion layers PB are used instead of the non-etching-through vias VB.

Referring to FIG. 4F, a third substrate 130 is provided or received, which includes one or more second bonding layers 126 and one or more anti-stiction layers 1341. Referring to FIG. 4G, the third substrate 130 is bonded to the second substrate 120 through the first bonding layers 104 and the second bonding layers 126 in a manner similar to that described with reference to FIG. 1J.

FIGS. 5A to 5F are cross-sectional views of intermediate structures for a method of manufacturing a semiconductor device 500, in accordance with some embodiments. In some embodiments, the semiconductor device 500 is a MEMS device, e.g., a sensor, such as a barometric pressure sensor, a motion sensor, an accelerometer, a gyroscope, or the like. In some embodiments, the semiconductor device 500 includes an optical element for transmitting or receiving optical signals (e.g., an optical waveguide), or an electromagnetic component for processing electromagnetic waves (e.g., an RF circuit). The semiconductor device 500 may be similar to the semiconductor device 100, 300 or 400 in many aspects, and these features are labelled with numerals similar to those used in FIGS. 1A to 1J and FIGS. 2A to 2H. Thus, details of these similar features are not repeated for brevity.

In some embodiments, the semiconductor device 500 is seen as a combination of the semiconductor device 100 and the semiconductor device 400. Referring to FIG. 5A, a second substrate 120 is provided or received. Referring to FIG. 5B, a third substrate 130 having a third bonding layer 134 and one or more anti-stiction layers 1341 is received or provided. The second substrate 120 is bonded to the third substrate 130 through the third bonding layer 134. According to some embodiments, one or more protrusion layers PB are formed on the upper surface of the second substrate 120 in a manner similar to that described with reference to FIG. 4D. In some embodiments, one or more second bonding layers 126 are formed on the upper surface of the second substrate 120 in a manner similar to that described with reference to FIG. 1H. The protrusion layers PB and the second bonding layers 126 may be formed of a same material or formed using a single deposition and patterning operation, and may be formed of different materials using separate deposition and patterning operations. In some embodiments, the steps shown in FIG. 5A and FIG. 5B are interchanged. In some embodiments, the one or more protrusions layers PB and the one or more second bonding layers 126 are formed on the upper surface of the second substrate 120 after the second substrate 120 is bonded to the third substrate 130.

Referring to FIG. 5C, a patterning operation is performed on the second substrate 120 to form one or more vias VX and one or more vias VA. Referring to FIG. 5D, a first substrate 110 is formed in a manner similar to that described with reference to FIGS. 1A to 1C. FIG. 5E shows a formation of the first bonding layer 104 over the first substrate 110 in a manner similar to that described with reference to FIG. 1D or 3D.

Referring to FIG. 5F, the third substrate 130 is bonded to first substrate 110 through the second substrate 120 in a manner similar to that described with reference to FIG. 3E. The protrusion layers PB and the non-etching-through vias VB can aid in reducing the contact area between the second substrate 120 and the first substrate 110 or the third substrate 130, respectively.

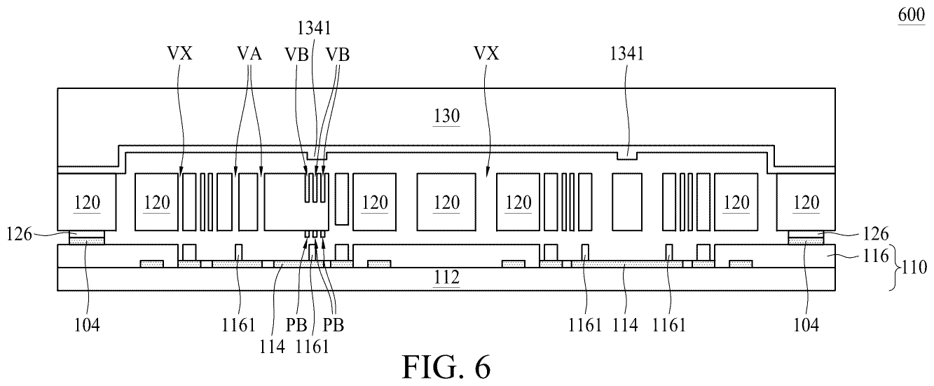

FIG. 6 is a cross-sectional view of a semiconductor device 600, in accordance with some embodiments. In some embodiments, the semiconductor device 600 is a MEMS device, e.g., a sensor, such as a barometric pressure sensor, a motion sensor, an accelerometer, a gyroscope, or the like. In some embodiments, the semiconductor device 600 includes an optical element for transmitting or receiving optical signals (e.g., an optical waveguide), or an electromagnetic component for processing electromagnetic waves (e.g., an RF circuit). The semiconductor device 600 may be similar to the semiconductor device 100, 300, 400 or 500 in many aspects, and these features are labelled with numerals similar to those used in FIGS. 1A to 1J and FIGS. 2A to 2H. Thus, details of these similar features are not repeated for brevity.

In some embodiments, the semiconductor device 600 is seen as a combination of the semiconductor devices 300 and 500, in which the formation of the non-etching through vias VB as shown in FIG. 3C are replaced with a formation of the protrusion layers PB. The formation of the vias VB shown in FIG. 6 is similar to that described with reference to FIGS. 1E and 1F. The protrusion layers PB and the non-etching-through vias VB can aid in reducing the contact area between the second substrate 120 and the first substrate 110 or the third substrate 130, respectively.

In some embodiments, any type of the anti-stiction structures, e.g., the etching-through vias VA, the non-etching-through vias VB, and the protrusion layers PB, can be used alone or in combination with other types of the snit-stiction structures in a semiconductor device 100, 300, 400, 500 and 600 for achieving contact area reduction of the movable membrane.

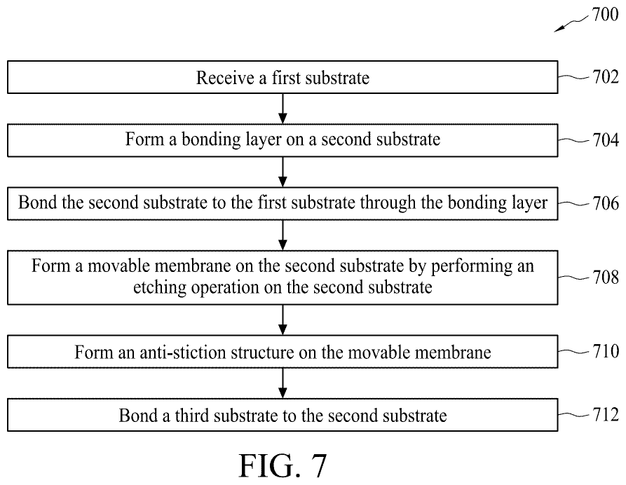

FIG. 7 is a flowchart of a method 700 of manufacturing a semiconductor device, in accordance with some embodiments. It shall be understood that additional steps can be provided before, during, and after the steps in method 700, and some of the steps described below can be replaced with other embodiments or eliminated. The order of the steps shown in FIG. 7 may be interchangeable. Some of the steps may be performed concurrently or independently.

At step 702, a first substrate is received. In some embodiments, the first substrate includes an electronic circuit.

At step 704, a bonding layer is formed on a second substrate.

At step 706, the second substrate is bonded to the first substrate through the bonding layer.

At step 708, a movable membrane is formed on the second substrate. In some embodiments, the forming of the movable membrane includes performing an etching operation to form a through via running through a thickness of the second substrate.

At step 710, an anti-stiction structure is formed on the movable membrane. The anti-stiction structure may be a via within the second substrate or a protrusion layer. In some embodiments, the forming of the via or the anti-stiction structure is performed in during the operation of forming the bonding layer on the second substrate or an etching operation to form the through via.

At step 712, a third substrate is bonded to the second substrate.

In accordance with some embodiments of the present disclosure, a method is provided. The method includes: receiving a first substrate; forming a bonding layer on a second substrate; bonding the second substrate to the first substrate; forming a movable membrane on the second substrate, the forming including performing an etching operation to form a through via through a thickness of the second substrate; and forming a first anti-stiction structure on a surface of the movable membrane. The forming of the first anti-stiction structure is performed at a same time as at least one of the etching operation of the through via and the forming of the bonding layer.

In accordance with some embodiments of the present disclosure, a method is provided. The method includes: bonding a first substrate to a bonding layer of a second substrate; and forming a movable membrane on the second substrate, the forming including forming a first via to define the movable membrane and an anti-stiction structure to reduce a contact area between the movable membrane and the first substrate. The anti-stiction structure includes at least one of a second via and a protrusion layer. The anti-stiction structure is formed during a formation of the bonding layer or the first via.

In accordance with some embodiments of the present disclosure, a semiconductor structure includes: a first substrate including an electronic circuit; and a second substrate bonded to the first substrate. The second substrate includes a movable membrane configured to move in response to a stimulus. The movable membrane includes: a first via configured as an etching-through via extending through a thickness of the movable membrane; and a second via configured as a non-etching-through via in the movable membrane. The first via includes a first sidewall has a first plurality of corrugation structures, and the second via includes a second sidewall has a second plurality of corrugation structures. Each of the first plurality of corrugation structures includes a first height greater than a second height of each of the second plurality of corrugation structures.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a first substrate;
forming a bonding layer on a second substrate;
bonding the second substrate to the first substrate;
forming a movable membrane on the second substrate, the forming comprising performing an etching operation to form a through via through a thickness of the second substrate; and
forming a first anti-stiction structure on a surface of the movable membrane,
wherein the forming of the first anti-stiction structure is performed at a same time as at least one of the etching operation of the through via and the forming of the bonding layer.

2. The method of claim 1, wherein the etching operation includes a deep reactive ion etching (DRIE) operation.

3. The method of claim 1, wherein the first anti-stiction structure is a non-etching-through via, and the etching operation leaves a plurality of corrugation structures on a first sidewall of the through via and a second sidewall of the first anti-stiction structure.

4. The method of claim 3, wherein a first number of corrugation structures on the first sidewall is less than a second number of corrugation structures on the second sidewall by a percentage between about 0% and about 40% of the second number.

5. The method of claim 3, wherein a first height of each corrugation structures on the first sidewall is greater than a second height of each corrugation structures on the second sidewall.

6. The method of claim 1, wherein of the first anti-stiction structure includes a plurality of vias.

7. The method of claim 6, wherein each of the plurality of vias tapers from a surface of the second substrate, wherein each of the plurality of vias forms a first obtuse angle with the surface of the movable membrane, and the through via forms a second obtuse angle, less than the first obtuse angle, with the surface of the movable membrane.

8. The method of claim 1, wherein the first anti-stiction structure comprises a protrusion layer protruding from a surface of the second substrate.

9. The method of claim 8, wherein the forming of the anti-stiction structure comprises forming the anti-stiction structure during the forming of the bonding layer.

10. The method of claim 1, wherein the first substrate comprises an anti-stiction layer facing the second substrate and overlapped with the first anti-stiction structure from top-view perspective.

11. A method, comprising:
bonding a first substrate to a bonding layer of a second substrate; and
forming a movable membrane on the second substrate, the forming comprising forming a first via to define the movable membrane and an anti-stiction structure to reduce a contact area between the movable membrane and the first substrate,
wherein the anti-stiction structure comprises at least one of a second via and a protrusion layer, wherein the anti-stiction structure is formed during a formation of the bonding layer or the first via.

12. The method of claim 11, wherein the forming of the first via comprises an etching operation that runs through a thickness of the movable membrane for forming the first via and stops at a depth substantially equal to or less than the thickness of the movable membrane for forming the second via.

13. The method of claim 12, wherein the etching operation comprising forming a passivation layer on a sidewall of each of the first via and the second via.

14. The method of claim 12, wherein the etching operation comprising forming first corrugation structures on a first sidewall of the first via and second corrugation structures on a sidewall of the second via, each of the first corrugation structures having a first height greater than a second height of each of the second corrugation structures.

15. The method of claim 12, wherein the etching operation further forms a plurality of third vias including the second via in an anti-stiction zone of the movable membrane, an area sum of the plurality of third vias is in a range between about 1% and about 95% of an area of the anti-stiction zone.

16. The method of claim 11, wherein the second via includes an aspect ratio between about 2 and about 500.

17. The method of claim 11, wherein the formation of the bonding layer comprises performing a patterning operation to form the bonding layer and the protrusion layer protruding from the second substrate.

18. A semiconductor structure, comprising:
a first substrate comprising an electronic circuit; and
a second substrate bonded to the first substrate, the second substrate comprising a movable membrane configured to move in response to a stimulus, wherein the movable membrane comprises:
a first via configured as an etching-through via extending through a thickness of the movable membrane; and
a second via configured as a non-etching-through via in the movable membrane,
wherein the first via includes a first sidewall having a first plurality of corrugation structures, and the second via includes a second sidewall having a second plurality of corrugation structures, wherein each of the first plurality of corrugation structures includes a first height greater than a second height of each of the second plurality of corrugation structures.

19. The semiconductor structure of claim 18, wherein the first sidewall forms a first obtuse angle with a surface of the movable membrane, and the second sidewall forms a second obtuse angle, greater than the first obtuse angle, with the surface of the movable membrane.

20. The semiconductor structure of claim 18, wherein the second via has a depth in a range between about 5% and 80% of the thickness of the movable membrane.
